(19) United States
(12) Patent Application Publication
(10) Pub. No.: US 2010/0034227 A1
(43) Pub. Date: Feb. 11, 2010

(54) INFRARED IMAGING USING MULTIPLE WAVELENGTHS

(75) Inventors: David C. Amundson, Boulder, CO (US); Larry Blankenship, Boulder, CO (US)

Correspondence Address: SCULLY SCOTT MURPHY & PRESSER, PC, 400 GARDEN CITY PLAZA, SUITE 300, GARDEN CITY, NY, 11530, US

(73) Assignee: OLYMPUS CORPORATION, Tokyo (JP)

(21) Appl. No.: 12/377,316

(22) PCT Filed: Aug. 14, 2007
(86) PCT No.: PCT/US07/18146

§ 371 Date: Mar. 31, 2009

Related U.S. Application Data
(60) Provisional application No. 60/837,502, filed on Aug. 14, 2006.

(51) Int. Cl. H01S 5/00; H01L 27/15; H01L 33/00

(52) U.S. Cl. 372/43.01; 257/79; 257/E33.044

(57) ABSTRACT

For an infrared imaging catheter, means of achieving a spread of wavelengths or multiple wavelengths through a stacking arrangement of “monochromatic” laser diodes or LED's are disclosed. Since a stack of diodes or LED's have different temperatures, they produce a wavelength spread many times greater than a single laser diode or LED. The wavelength spread reduces speckle in the corresponding image. Adding wavelengths also improves the corresponding infrared image, since different wavelengths have different light penetration capabilities and can emphasize different biological entities.

### BACKGROUND

U.S. Pat. No. 6,178,346, describes a means of imaging through flowing blood by selecting a monochromatic wavelength in one of the low-absorbance regions in the infrared. These regions are 800-1350 nm, 1500-1850 nm and 2100-2300 nm as well as higher regions. Any wavelength in these regions will have sufficiently low absorption and scattering to penetrate centimeters of blood to image cardiovascular structures. Not discussed in U.S. Pat. No. 6,178,346, is the use of multiple wavelengths to image through flowing blood or the precise meaning of the term “monochromatic”. These multiple wavelengths can be from the same infrared region or from different regions.

The term “monochromatic” is usually defined as (a) of one color or (b) having a single wavelength or narrow band of wavelengths In the implementation of a precise-wavelength laser diode, it has been found necessary to stack a number of laser diodes to achieve the necessary power (about 10 watts) to image through flowing blood. For example, the current laser diode configuration consists of a 3×3 array of laser diodes coupled with a heat sink to dissipate the heat from the diodes. Laser diodes emit different wavelengths depending on the temperature of the laser diode. In a 3×3 stack, there is a temperature differential among the laser diodes. The temperature differential gives rise to a spread of wavelengths of 100-150 nm.

U.S. Pat. No. 6,178,346 states that possible light sources include filtered incandescent, LED's and laser diodes (line 50 Column 37).

The wavelength regions identified in U.S. Pat. No. 6,178,346 include regions with varying degrees of scattering and absorption. Scattering is inversely proportional to the inverse square of the wavelength. Absorption differs for each wavelength based on its proximity to light resonances related to stretching or rotating the water molecule. As a consequence of the scattering and absorption, the infrared image of each of these regions varies in its clarity (related to scattering) and light penetration (related to absorption):

The practical implementation of these light sources, produce a wide range of wavelengths, even though they are produced from “monochromatic” sources such as a laser diode or LED.

### INVENTION SUMMARY

Described is a multi-wavelength approach to imaging through flowing blood. Multi-wavelengths can be achieved by either stacking laser diodes or light emitting diodes (LED's) of the same wavelength and having them operate in a different temperature environment or from deliberately selecting different wavelengths to form the diode array.

There are two advantages of multiple wavelengths:
1. A wavelength spread is beneficial since it eliminates the speckle caused from the use of a single wavelength.
2. Wavelengths can be selected from different infrared regions to improve the background characteristics of the image or the clarity of the image.

The implementation described in this patent application is an array of diodes where either a temperature differential exists among the diodes or the diodes are selected of different wavelengths.

### FIGURES

FIG. 1. A drawing of a single laser diode and corresponding wavelength distribution

FIG. 2. A drawing of the laser diode configuration showing a 3×3 diode array with each laser specified at the same wavelength and the corresponding wavelength distribution.

FIG. 3. A drawing of the laser diode configuration showing a 3×3 diode array with three different wavelengths and the corresponding wavelength distribution.

FIG. 4. A drawing of a 6×3 stacked array of laser diodes of wavelengths 1300, 1550, and 1800 nm and its corresponding graph of wavelength distribution

### DETAILED EMBODIMENTS

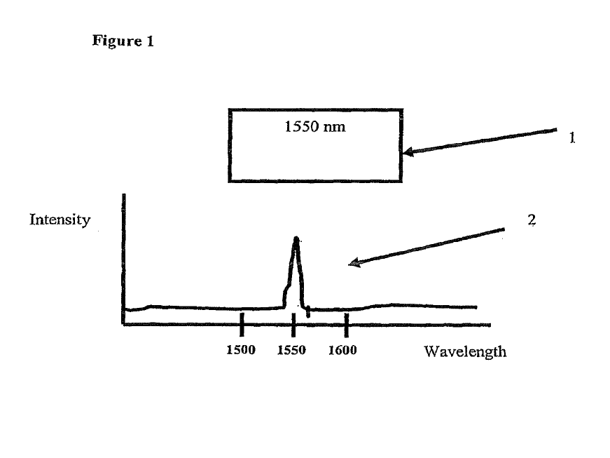

FIG. 1 shows a single laser diode (1) and the corresponding intensity versus wavelength graph (2). As can be seen, the spread in wavelength is about 10-15 nm. However, a single laser diode is insufficient to create enough wattage to be capable of imaging through centimeters of blood. To create the approximate 10 watts of energy a the laser diode level, corresponding to about 2 watts at the end of the catheter, diodes need to be connected in a stack

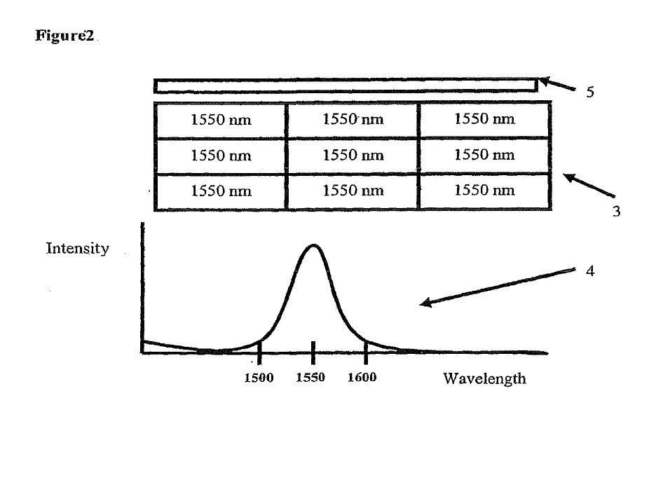

FIG. 2 shows a 3×3 stack of laser diodes (3) with a heat sink (5) placed above the stack to dissipate heat. A consequence of this arrangement is that there is a temperature differential across the laser stack. Since the wavelength of a laser diode depends on the operating temperature of the diode, this results in a wavelength spread of about 50-100 nm which is shown on the intensity versus wavelength graph (4). Spreading the wavelength is desirable since it reduces speckle on the infrared image.

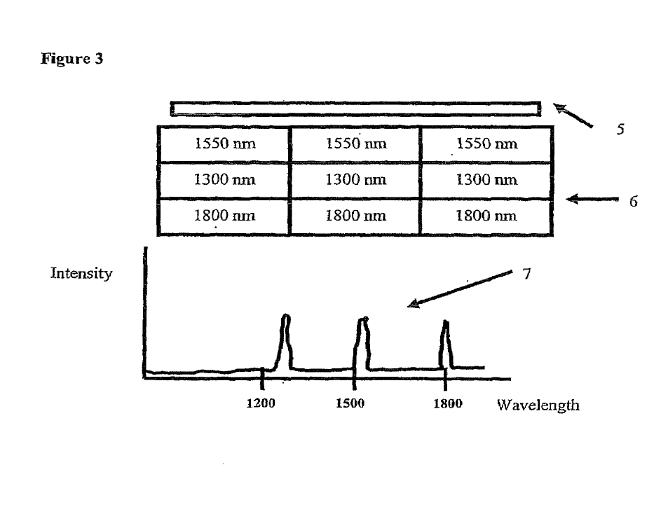

FIG. 3 shows a 3×3 stack of laser diodes (6) with three different wavelengths utilized. Wavelengths are chosen at 1300 nm, 1550 nm and 1800 nm. The resulting intensity versus wavelength (7) now shows three peaks corresponding to each wavelength. Employing three wavelengths improves the infrared image since adding 1300 nm and 1800 nm improves imaging depth and clarity. Different wavelengths are absorbed by blood differently. The attenuation through blood is governed by the Beer's equation of 1(in) I(x cm) exp(−xA), where A is the absorption coefficient, x is the distance of the structure in cm, I(in) is the light intensity at the source and I(x cm) in the intensity at x cm.. At 1300 nm, the absorption coefficient through blood is about 0.1/cm, at 1550 nm it is about 5 and at 1800 nm it is about 4. Thus, light at 1300 nm will penetrate through blood about 50 times a greater distance than light at 1550 nm. However, the scattering by red blood cells is proportional to the inverse of the square of the wavelength. So images created by 1300 nm will penetrate blood to a much greater extent, but the increased scattering by red blood cells will compromise its clarity. At a wavelength of 1800 nm, the scattering will be least but it will suffer significant attenuation due to its absorption coefficient of 4/cm. It inclusion will highlight different biological material differently from 1550 nm since abaorbance resonances for different biological materials occurs at different wavelengths. The composite of 1300 nm, 1550 nm and 1800 nm produces an enhanced infrared image since the 1300 nm light provides important background information and the 1550 nm and 1800 nm light produce higher resolution images at two different biological absorption regions.

Other wavelength combinations could also be used effectively. For example, 1300, 1550 and 1720 nm are suited for examining arteries with vulnerable plaque. The lipid pool inside the vulnerable plaque cap have an absorbance peak of about 1720 nm. Irradiating at 1720 will reveal the presence of a lipid pool when combined with the other two wavelengths.

The laser diode arrangement shown in FIG. 3 provides two wavelengths (1550 nm and 1800 nm), which create infrared images of good clarity but are limited in their ability to penetrate blood. Furthermore, using these two wavelengths emphasizes different biological materials. For example, lipids may appear with greater intensity at 1800 nm than at 1550 nm, because they have greater absorption at 1800 nm. However, the infrared image is compromised at these two wavelengths by the high absorption coefficient, which have the effect of eliminating structures that are centimeters away from the primary structure imaged. For example, 1550 nm light which illuminates a structure one centimeter away will suffer a round-trip attenuation of exp(−2×5)=exp(−10). This large attenuation prevents the, registering of the structure one centimeter away from the primary structure on the infrared image. As a result, the infrared image of a structure frequently shows the primarily structure with a black background because of the high absorption coefficient of these wavelengths. Adding 1300 nm greatly improves the background, producing images with backgrounds more similar to visible light images where the absorption is even lower. This occurs because the structure one centimeter away from the primary structure imaged is only attenuated exp(−2×0.1)=exp(−0.2).

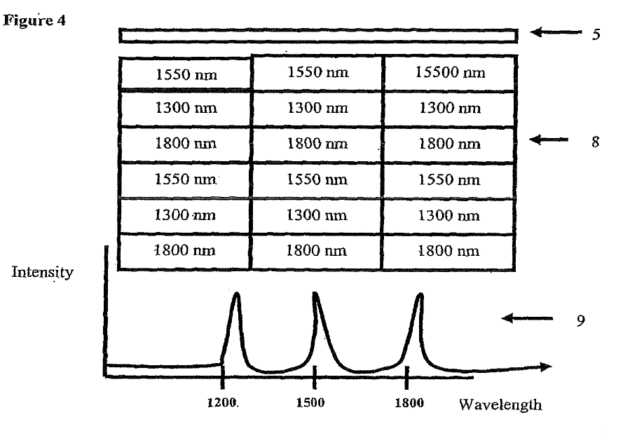

FIG. 4 shows a double stack of the lasers depicted in FIG. 3. A stack of 6×3 laser diodes (8) now incorporates two wafers at wavelengths 1300 nm, 1550 nm and 1800 nm. The result of this configuration is shown in the intensity versus wavelength graph (9). Now the wavelength spread of each wavelength in about 100-150 nm due to the fact that the two wafers of the same wavelength and at different temperatures. The advantage of this configuration is a doubling of the wattage and the elimination of speckle at each wavelength.

In a similar manner, instead of using laser diodes, light-emitting diodes (LED's) could be used instead. An individual LED has a wavelength spread of 100-150 nm. Stacking LED's in a similar arrangement as above would result in a temperature differential, which increases the wavelength spread to 300-600 nm. LED's could be used in all the configurations discussed above. For example, in the configuration in FIG. 4 with the LED's replacing the laser diodes, the wavelength regions covered (assuming a 400 nm spread in wavelength) would be 1100-1500 nm, 1250-1850 nm and 1500-2100 nm.

In summary, this patent discloses means of achieving a spread of wavelengths or multiple wavelengths through a stacking arrangement of “monochromatic” laser diodes or LED's. Since a stack of diodes or LED's have different temperatures, they produce a wavelength spread many times greater than a single laser diode or LED. The wavelength spread reduces speckle in the corresponding image Adding wavelengths also improves the corresponding infrared image, since different wavelengths have different light penetration capabilities and can emphasize different biological entities.

1. A device for imaging through flowing blood comprising an array of diodes, wherein at least some of the diodes in the array are operating at different wavelength ranges for at least some of the other diodes in the array.

2. The device of claim 1, wherein at least some of the diodes operate at different temperatures from at least some of the other diodes in the array.

3. The device of claim 1 comprising laser diodes.

4. The device of claim 1 comprising light emitting diodes.
